(19) United States
(12) Patent Application Publication
(10) Pub. No.: US 2018/0312967 A1
(43) Pub. Date: Nov. 1, 2018

(54) SUBSTRATE PROCESSING APPARATUS, METHOD OF REMOVING PARTICLES IN INJECTOR, AND SUBSTRATE PROCESSING METHOD

(71) Applicant: TOKYO ELECTRON LIMITED, Tokyo (JP)

(72) Inventor: Katsutoshi ISHII, Nirasaki City (JP)

(21) Appl. No.: 15/959,629

(22) Filed: Apr. 23, 2018

(30) Foreign Application Priority Data
Apr. 27, 2017 (JP) 2017-088690

(51) Int. Cl. C23C 16/44; C23C 16/455

(52) U.S. Cl. CPC C23C 16/4405; C23C 16/45563; C23C 16/4412

(57) ABSTRACT

There is provided a substrate processing apparatus, including: a process vessel configured to accommodate and process a substrate; a first injector located inside the process vessel and configured to discharge a first processing gas into the process vessel; a processing gas supply pipe located outside of the process vessel and connected to the first injector and configured to supply the first processing gas to the first injector; a first valve located in the processing gas supply pipe; an exhaust part configured to exhaust the process vessel; a bypass pipe branched at a predetermined position closer to the process vessel than the first valve in the processing gas supply pipe and configured to connect the processing gas supply pipe to the exhaust part; and a second valve located in the bypass pipe.

### CROSS-REFERENCE TO RELATED APPLICATION

This application is based upon and claims the benefit of priority from Japanese Patent Application No. 2017-088690, filed on Apr. 27, 2017, the entire contents of which are incorporated herein by reference.

### TECHNICAL FIELD

The present disclosure relates to a substrate processing apparatus, a method of removing particles in an injector, and a substrate processing method.

### BACKGROUND

A cleaning method has been used that uses a reaction tube for performing a predetermined process on a substrate, a plurality of nozzles for supplying a reaction gas into the reaction tube, and a cleaning nozzle which is installed separately from the plurality of nozzles and supplies a cleaning gas into the reaction tube. In this method, when cleaning the interior of the nozzles, nozzles to be cleaned are sequentially selected, a cleaning gas is supplied to a selected nozzle, and an inert gas is supplied to unselected nozzles. Further, the cleaning gas is supplied to the selected nozzle, and subsequently, the inert gas is supplied to the respective nozzle. Further, when cleaning the interior of the reaction tube, the cleaning gas is supplied at least from the cleaning nozzle into the reaction tube, and the inert gas is supplied to the cleaned nozzle.

In such a cleaning method, the cleaning gas is supplied into the nozzle to clean the interior of the nozzle. Further, when cleaning the reaction tube, the inert gas is supplied to the cleaned nozzle to prevent over-etching of an inner wall of the respective nozzle.

In the configuration disclosed above, since the interior of the nozzle is cleaned with a cleaning gas, it is possible to prevent particles derived during film formation from forming, namely particles caused by delamination of a film. However, the configuration fails to remove particles which are delaminated and separated due to weakening of a glass surface of a nozzle made of quartz, namely quartz-derived particles. That is to say, even if one kind of gas is supplied from a nozzle for supplying a film-forming gas, another gas scattered inside the reaction tube flows into the nozzle through discharge holes of the nozzle. Thus, a reaction product may often be generated by reaction between the gases so that a film is formed inside the nozzle.

The film delamination in the interior of the nozzle causes the particles. In addition, stress may be applied to an inner surface of the nozzle through repeated expansion and contraction of the film. This weakens the surface of the quartz due to a difference in absolute values of linear expansion coefficients between a quartz glass constituting the nozzle and the film. This generates quartz pieces, which may cause particles. With the cleaning gas, the particles derived from the film can be removed, but the quartz-derived particles cannot be removed.

### SUMMARY

The present disclosure provides some embodiments of a substrate processing apparatus capable of effectively removing not only particles in a nozzle but also particles derived from quartz, a method of removing particles in an injector, and a substrate processing method.

According to one embodiment of the present disclosure, there is provided a substrate processing apparatus, including: a process vessel configured to accommodate and process a substrate; a first injector located inside the process vessel and configured to discharge a first processing gas into the process vessel; a processing gas supply pipe located outside of the process vessel and connected to the first injector and configured to supply the first processing gas to the first injector; a first valve located in the processing gas supply pipe; an exhaust part configured to exhaust the process vessel; a bypass pipe branched at a predetermined position closer to the process vessel than the first valve in the processing gas supply pipe and configured to connect the processing gas supply pipe to the exhaust part; and a second valve located in the bypass pipe.

According to another embodiment of the present disclosure, there is provided a method of removing particles in an injector, including: connecting a processing gas supply pipe which is connected to a first injector installed inside a process vessel and configured to supply a first processing gas into the process vessel, to an exhaust part; and exhausting, by the exhaust part, an interior of the first injector via the processing gas supply pipe.

According to another embodiment of the present disclosure, there is provided a substrate processing method, including: performing the aforementioned method; closing the second valve provided in the bypass pipe and opening the third valve provided in the exhaust pipe to exhaust an interior of the process vessel by the exhaust part; and opening the first valve located in the processing gas supply pipe to supply the first processing gas from the first injector into the process vessel and to process a substrate inside the process vessel.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a diagram illustrating an example of a substrate processing apparatus according to an embodiment of the present disclosure.

FIG. 2 is an enlarged view of an injector.

FIG. 3 is a diagram illustrating a method of removing particles in the injector according to an embodiment of the present disclosure.

FIGS. 4A and 4B are views illustrating a flow of gas in the injector.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

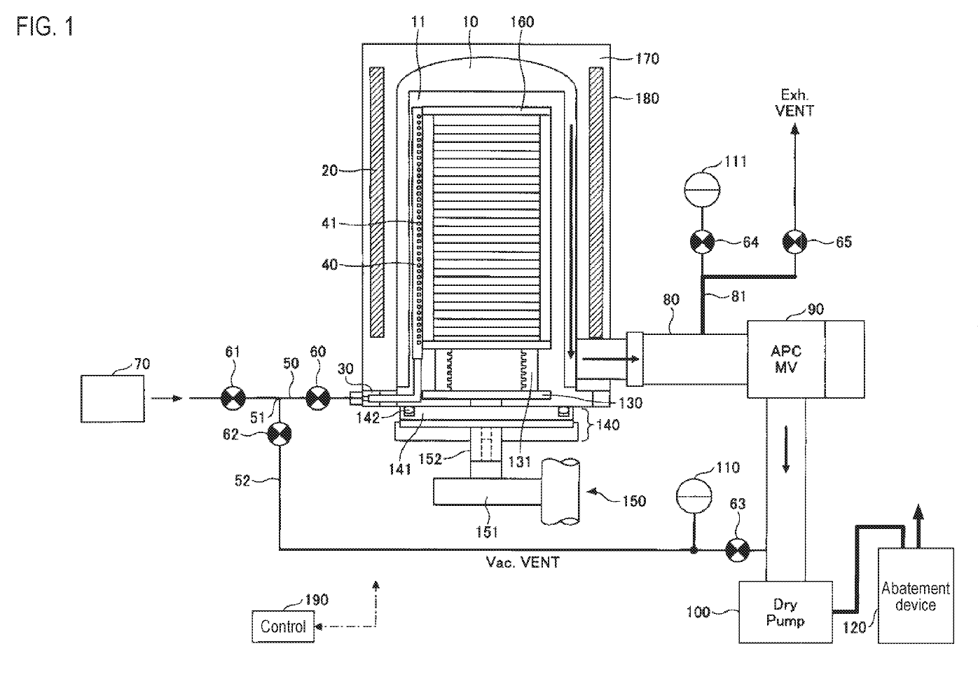

FIG. 1 is a diagram illustrating an example of a substrate processing apparatus according to an embodiment of the present disclosure. As illustrated in FIG. 1, the substrate processing apparatus according to the present embodiment includes a reaction tube 10, an inner tube 11, a heater 20, a manifold 30, an injector 40, a processing gas supply pipe 50, a bypass pipe 52, valves 60 to 65, a processing gas supply source 70, an exhaust pipe 80, a bypass exhaust pipe 81, an automatic pressure control valve (APC MV) 90, a vacuum pump 100, a manometer 110, a harmful substance removing device 120, a table 130, a mounting table 131, a lid 140, an elevating mechanism 150, a wafer boat 160, a heat insulating member 170, a housing 180, and a control part 190. Furthermore, the injector 40 includes a plurality of discharge holes 41. The lid 140 includes a flange portion 141. The elevating mechanism 150 includes an arm 151 and a rotary shaft 152. In addition, a plurality of wafers W is mounted in the wafer boat 160.

The substrate processing apparatus illustrated in FIG. 1 is configured as a vertical heat treatment apparatus in which a plurality of wafers W is vertically stacked at predetermined intervals in the wafer boat 160 and is heated by the heater 20 while supplying a processing gas from the injector 40 into the reaction tube 10, specifically the inner tube 11, thus forming a film on each wafer. The substrate processing apparatus according to the present embodiment may be applied to various substrate processing apparatuses as long as they perform a substrate process using an injector. In the present embodiment, an example in which the substrate processing apparatus is configured as a vertical heat treatment apparatus will be described.

The reaction tube 10 and the inner tube 11 constitute a process vessel which accommodates the wafers W mounted in the wafer boat 160 and performs a heat treatment with respect to the wafers W. The reaction tube 10 and the inner tube 11 have a substantially cylindrical shape and also have a height at which several tens to 100 sheets of wafers W vertically stacked in the wafer boat 160 are processed in a batch manner at a time. Furthermore, the reaction tube 10 and the inner tube 11 may be made of various materials, for example, quartz. Although not illustrated in FIG. 1, a ceiling of the inner tube 11 is opened, or a slit is formed in a lateral surface of the inner tube 11 at the side of the exhaust pipe 80. The interior of the inner tube 11 can be exhausted by the vacuum pump 100.

A lower end of the reaction tube 10, namely a bottom surface of the reaction tube 10, is opened. The wafer boat 130 in which the wafers W are mounted is transferred through the opened lower end.

The heater 20 is a heating means which is installed around the reaction tube 10 and heats the wafers W loaded into the inner tube 11 from the outside.

The manifold 30 is connected to the processing gas supply pipe 50 for supplying a processing gas to the injector 40 installed inside the reaction tube 10 and is brought into communication with the injector 40 installed inside the reaction tube 10. The manifold 30 has a shape whose outer periphery protrudes outward, such as a flange.

The injector 40 is a gas supply means for supplying the processing gas into the reaction tube 10, specifically the inner tube 11. The injector 40 is inserted into the inner tube 11 from the manifold 30 and is configured to vertically extend along an inner peripheral surface of the inner tube 11. The injector 40 supplies the processing gas from the plurality of discharge holes 41 formed inward of the inner tube 11 toward the wafers W. In addition, in the case where the substrate processing apparatus performs a film forming process, a gas necessary for film formation is supplied as the processing gas, and in the case where the substrate processing apparatus performs other processes, gases adapted for the respective processes is supplied as the processing gas depending on the intended use. The injector 40 is made of quartz.

In FIG. 1, although only one injector 40 is illustrated for easily understanding the figure, a plurality of injectors may be installed. In the case where the substrate process performed in the substrate processing apparatus is a film forming process, plural kinds of processing gases which react with each other to generate a reaction product are often supplied. In the case of the processing gas for film formation, a combination of a raw material gas such as a silicon-containing gas, an organic metal-containing silicon-based gas or the like, and an oxidizing gas for oxidizing the raw material gas or a nitriding gas for nitriding the raw material gas is often used as the processing gas for film formation. Examples of the oxidizing gas may include ozone, oxygen, water or the like. An example of the nitriding gas may include ammonia. In some embodiments, an injector for purge gas supply for supplying a purge gas to the wafers W so as to purge the wafers W may be installed. Examples of the purge gas may include a noble gas such as Ar, He or the like in addition to an inert gas represented by a nitrogen gas. In a case where a plurality of injectors is installed, the plurality of injectors may be arranged along a circumferential direction of the substantially cylindrical reaction tube 10.

The other end of the processing gas supply pipe 50, which is not connected to the reaction tube 10, is connected to the processing gas supply source 70. Thus, the processing gas can be supplied from the processing gas supply source 70 to the injector 40 via the gas supply pipe 50.

The bypass pipe 52 is branched at a branch point 51 of the processing gas supply pipe 50. The bypass pipe 52 is connected to the exhaust pipe 80 and is also connected to the vacuum pump 100 via the exhaust pipe 80. The bypass pipe 52 is a pipe used for removing particles existing in the injector 40.

The valves 60 and 61 are installed in the processing gas supply pipe 50. The valves 62 and 63 are installed in the bypass pipe 52. The valve 60 is a valve used for cutting off the connection between the processing gas supply source 70 and the injector 40. In the present embodiment, the valve 60 is not essential, but may be installed as necessary. The valve 61 is a valve for cutting off the connection between the bypass pipe 52 and the processing gas supply source 70, and is kept closed when removing particles existing in the injector 40, while being kept opened in other cases.

The valve 62 is a valve for switching the connection and disconnection between the bypass pipe 52 and the processing gas supply pipe 50. The valve 63 is a valve for switching the connection and disconnection between the bypass pipe 52 and the exhaust pipe 80. The valve 63 is not essential in the present embodiment, but may be provided as necessary.

Details of the operation of the valves 60 to 63 will be described later.

The processing gas supply source 70 is a gas storage source for supplying the processing gas to the injector 40. The processing gas supply source 70 can supply various processing gases to the injector 40 depending on the intended use. For example, the raw material gas used when performing the film forming process may be supplied to the injector 40.

The exhaust pipe 80 is a pipe for exhausting the interior of the reaction tube 10 and is connected to an exhaust means such as the vacuum pump 100 such that the interior of the reaction tube 10 can be exhausted. In addition, the automatic pressure control valve 90 for automatically adjusting an internal pressure of the exhaust pipe 80 is installed in the exhaust pipe 80.

The bypass pipe 52 is connected to the exhaust pipe 80 between the automatic pressure control valve 90 and the vacuum pump 100. Accordingly, the interior of the injector 40 can be exhausted using the vacuum pump 100 through the exhaust pipe 80 and the bypass pipe 52.

The vacuum pump 100 is an exhaust means for vacuum-exhausting the interior of the reaction tube 10. For example, a dry pump is used as the vacuum pump 100. The vacuum pump 100 is not limited to the dry pump but various exhaust means may also be used as long as they can exhaust the interior of the reaction tube 10.

In addition, the manometer 110 is installed in the bypass pipe 52 so as to measure an internal pressure of the bypass pipe 52,

The bypass exhaust pipe 81 is a pipe used when the pressure automatic control valve 90 is closed to measure the internal pressure of the exhaust pipe 80 or set an internal pressure of the reaction tube 10 to an atmospheric pressure, especially when the internal pressure is excessively increased, or the like. In the case of measuring the internal pressure of the exhaust pipe 80, the valve 64 is opened to measure the internal pressure by the manometer 111. On the other hand, when lowering the lid 140, the internal pressure of the reaction tube 10 is set to an atmospheric pressure. In the case where the internal pressure of the reaction tube 10 becomes higher than the atmospheric pressure, the valve 65 is opened to lower the internal pressure of the reaction tube 10.

The harmful substance removing device 120 is a device which is installed at a downstream side of the vacuum pump 100 and changes a harmful substance into a harmless substance.

The table 130 is a support table for supporting the mounting table 131 on which the wafer boat 160 is mounted.

The mounting table 131 is a support table which is installed on the table 130 to mount and support the wafer boat 160 together with the table 130. The table 130 and the mounting table 131 may be made of, for example, quartz.

The lid 140 is a covering member that can seal the lower end opening of the reaction tube 10. The flange portion 141 having a sealing material 142 provided in its upper surface is installed at an upper portion of the lid 140 so as to seal the opening of the reaction tube 10. The flange portion 141 may be made of, for example, quartz. Although not illustrated in FIG. 1, the sealing material 142 may be configured such that the lid 140 hermetically seals the opening of the reaction tube 10 in a state where the sealing material 142 is brought into contact with a portion of the bottom surface of the outer periphery of the reaction tube 10.

The elevating mechanism 150 is a mechanism for raising and lowering the lid 140, and includes the arm 151 and the rotary shaft 152. The rotary shaft 152 is installed at a leading end of the arm 151 supported by the elevating mechanism 150 and passes through the lid 140 to support the table 130 at a tip of the lid 140. Accordingly, the substrate process can be performed while rotating the wafer boat 160 with the rotary shaft 152 in a state where the lid 140 is fixed without rotation. The elevating mechanism 150 is configured to integrally move the wafer boat 160 and the lid 140 up and down, and to rotate only the table 130, the mounting table 131 and the wafer boat 130. In some embodiments, the table 50 may be fixedly installed on the lid 140 to perform the processing of the wafers W without rotating the wafer boat 160.

Thus, the lid 140 is configured to be raised and lowered while supporting the wafer boat 160 on which the wafers W are mounted. The lid 140 is configured to seal the lower end opening of the reaction tube 10 while supporting the wafer boat 160. Accordingly, the wafer boat 160 is carried into and out of the reaction tube 10 by raising and lowering the lid 140 in a state in which the wafer boat 160 is supported above the lid 140.

As described above, the wafer boat 160 is a substrate holder that can horizontally hold the plurality of wafers W at predetermined intervals in the vertical direction. Further, the wafer boat 160 may be made of, for example, quartz glass or SiC.

The heat insulating member 170 is a means for preventing heat generated from the heater 20 from leaking, and is installed to cover the reaction tube 10 and the heater 20.

The housing 180 is a housing means for covering the entire vertical heat treatment apparatus. The inside of the housing 180 is filled with the heat insulating member 170 to suppress the heat from being radiated to the outside.

The control part 190 is means for controlling the overall vertical heat treatment apparatus. The control part 190 also controls the switching of the opening and closing operations of the valves 60 to 65 and the operation of the vacuum pump 100. The control part 190 may be configured by various operation processing means. For example, the control part 190 may include a central processing unit (CPU) and a memory such as a read only memory (ROM) or a random access memory (RAM), and may be configured as a microcomputer that operates according to a program. Further, the control part 190 may be configured by an integrated circuit such as an application specific integrated circuit (ASIC) into which a plurality of functional circuits is combined for a specific purpose. The control part 190 has an operation processing function and may be configured by various means as long as they can control the overall heat treatment apparatus.

The vertical heat treatment apparatus includes a wafer transfer mechanism for transferring the wafers W from a wafer cassette such as a front opener unified pod (FOUP) to the wafer boat 160, or the like, in addition to the configuration illustrated in FIG. 1. These components are less related to features of the substrate processing apparatus according to the present embodiment, and therefore, the illustration and description thereof will be omitted in the present embodiment.

Next, an operation of the vertical heat treatment apparatus illustrated in FIG. 1 when performing a film forming process will be described. When the vertical heat treatment apparatus performs the film forming process, the wafer boat 160 is mounted on the mounting table 131 above the lid 140 in a state in which a plurality of, for example, about 50 to 100 sheets of wafers W, is mounted in the wafer boat 160. The lid 140 is raised to seal the interior of the reaction tube 10 so that the wafers W are located inside the reaction tube 10.

Subsequently, the interior of the reaction tube 10 is vacuum-exhausted by operating the vacuum pump 100 such that the internal pressure of the reaction tube 10 reaches a predetermined degree of vacuum.

Subsequently, a processing gas is supplied from a plurality of injectors including the injector 40. As the processing gas, various gases may be selected depending on the intended use. For example, in a case of forming a silicon oxide film, a silicon-containing gas and an oxidizing gas are supplied as the processing gas. The silicon-containing gas may be, for example, an aminosilane gas. The oxidizing gas may be, for example, an ozone gas. As the aminosilane gas and the ozone gas react with each other, a silicon oxide is deposited as a reaction product on the wafer W to form a silicon oxide film.

In a case of chemical vapor deposition (CVD) film formation, the aminosilane gas and the ozone gas are simultaneously supplied into the reaction tube 10. On the other hand, in a case of atomic layer deposition (ALD) film formation, only the aminosilane gas is initially supplied into the reaction tube 10 to be adsorbed onto the surface of the wafer W. Thereafter, the interior of the reaction tube 10 is purged with a purge gas. Then, the ozone gas alone is supplied into the reaction tube 10 to react with the aminosilane gas adsorbed onto the surface of the wafer W. As a result, a layer composed of the silicon oxide film is formed on the surface of the wafer W. Thereafter, the purge gas is supplied into the reaction tube 10, and subsequently, a cycle including the supply of the aminosilane gas, the supply of the purge gas, the supply of the ozone gas, and the supply of the purge gas is repeated so that the layer composed of the silicon oxide film is gradually deposited on the surface of the wafer W.

In this manner, the silicon oxide film can be formed on the surface of the wafer W. The processing gas used at this time is supplied from the processing gas supply source 70 to the injector 40 via the processing gas supply pipe 50. That is to say, the valve 62 of the bypass pipe 52 is closed, and the valves 60 and 61 of the processing gas supply pipe 50 are opened to supply the processing gas from the injector 40 into the reaction tube 10 (more specifically, into the inner tube 11).

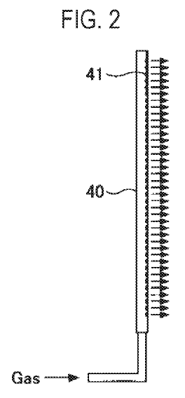

FIG. 2 is an enlarged view of the injector 40. As illustrated in FIG. 2, the injector 40 is formed as a quartz tube extending in the vertical direction. The plurality of discharge holes 41 is formed in the injector 40 along the vertical direction such that the processing gas is injected from the discharge holes 41 to be supplied onto each of the wafers W.

However, since the inner tube 11 is in an environment where the silicon oxide film is formed, the aminosilane gas and the ozone gas dispersedly float. In addition, the film forming process is performed in a state which the aminosilane gas and the ozone gas are at a temperature (for example, at 600 degrees C. or higher) at which they are decomposed. As such, there may be a situation where the ozone gas is mixed inside the injector 40 that currently supplies the aminosilane gas so that the silicon oxide film is formed inside the respective injector 40, or a situation where the aminosilane gas is mixed inside the injector 40 that currently supplies the ozone gas so that the silicon oxide film is formed inside the respective injector 40. In addition, if the silicon oxide film adhering to the inner wall of the injector 40 is contracted, a stress may be applied to the injector 40 when the silicon oxide film is expended. This weakens the quartz glass constituting the injector 40 to generate particles of quartz pieces.

For this reason, in the substrate processing apparatus according to the present embodiment, the operation of removing the quartz-derived particles generated inside the injector 40 is performed before the start of the film formation process.

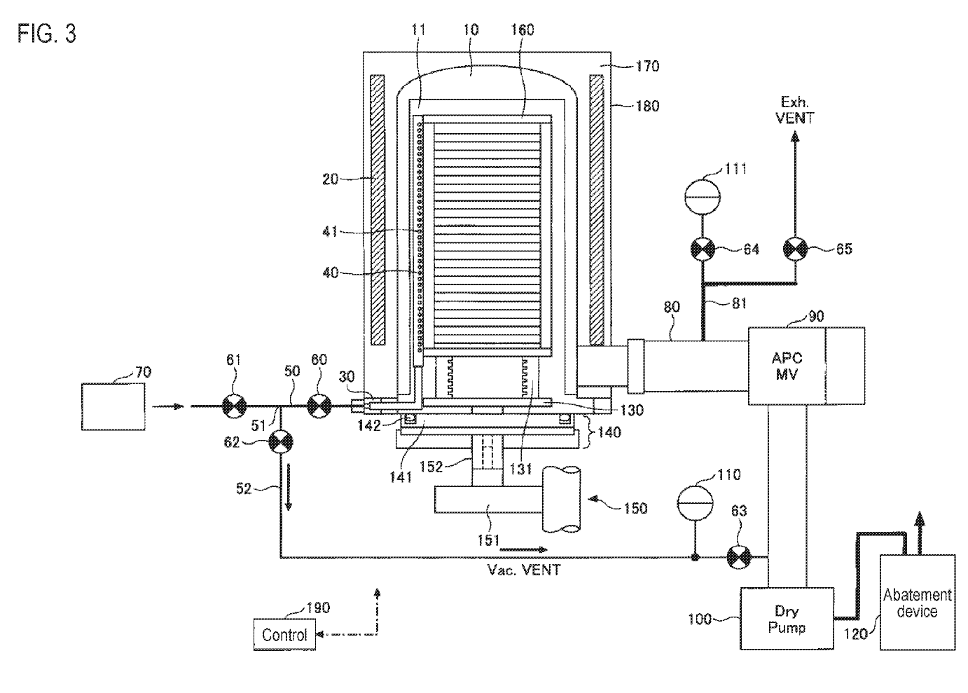

FIG. 3 is a diagram illustrating a method of removing particles existing in the injector according to an embodiment of the present disclosure. Components illustrated in FIG. 3 are the same as those in FIG. 1, and therefore, the same components are designated by like reference numerals with the descriptions thereof omitted.

In the particle removing method according to the present embodiment, in an initial state, the valve 61 is kept closed and the valve 62 is kept opened. Furthermore, the valve 63 is installed in the bypass pipe 52. When the valve 63 remains closed, the valve 63 is switched to be opened. That is to say, the connection path between the injector 40 and the processing gas supply source 70 is blocked by the valve 61, and the valve 62 and the valve 63 are opened such that the connection path between the injector 40 and the vacuum pump 100 is formed through the bypass pipe 52. Thus, the interior of the injector 40 can be vacuum-exhausted by the vacuum pump 100. Since the valve 60 is kept open even at the time of film formation, the valve 60 remains opened. Therefore, the valve 60 may be omitted.

In some embodiments, the automatic pressure control valve 90 may be switched from the opened state to the closed state, but is not necessarily essential. Thus, the interior of the reaction tube 10 may not be exhausted by the vacuum pump 100. That is to say, by avoiding the dispersal exhaust process, it is possible to exhaust the interior of the injector 40 with a strong exhaust power.

By exhausting the interior of the injector 40P in this manner, it is possible to remove particles existing in the injector 40. Since the removal of the particles is performed by virtue of the exhaust power, it is possible to remove not only the particles derived from quartz but also the particles derived from film formation, regardless of the nature of the particles.

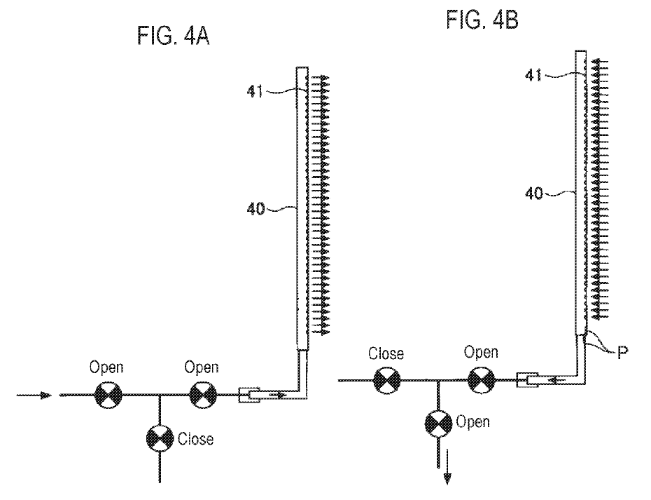

FIGS. 4A and 4B are views illustrating a flow of gas in the injector 40. FIG. 4A is a view illustrating a gas flow during the normal film formation, and FIG. 4B is a view illustrating a gas flow when the method of removing particles existing in the injector 40 is performed,

As illustrated in FIGS. 4A and 4B, at the time of the normal film formation illustrated in FIG. 4A, the processing gas is injected from the discharge holes 41 of the injector 40, whereas at the time of the particle removal illustrated in FIG. 4B, the gas in the reaction tube 10 is sucked into the discharge holes 41 of the injector 40 such that the particles in the injector 40 are effectively removed from a lower portion P of the injector 40 to which the particles are likely to adhere. By exhausting the interior of the injector 40 in this way, it is possible to effectively remove the particles from the interior of the injector 40.

The opening and closing of the valves 60 to 63 and the automatic pressure control valve 90 as described above may be performed, for example, under the control of the control part 190.

If the method of removing particles in the injector 40 is performed before the start of the film forming process, the film forming process can be performed in a state in which the particles in the injector 40 has been removed. Thus, it is possible to prevent the particles in the injector 40 from scattering on the wafers W and to perform a high quality film forming process.

Furthermore, after the method of removing particles in the injector 40 as described above is performed, the valves 62 and 63 in the bypass pipe 52 are closed and the pressure automatic control valve 90 is opened. After the internal pressure of the reaction tube 10 reaches a predetermined pressure (predetermined degree of vacuum), the valve 61 is opened to start the supply of the processing gas from the processing gas supply source 70 to the injector 40. This makes it possible to smoothly return to the normal film forming operation.

In addition, the method of removing particles in the injector 40 according to the present embodiment may be appropriately performed before the start of the film formation process. For example, the removal method may be performed each time before the start of the film formation process, or may be performed once every several film formation processes. Furthermore, the frequency of performing the method of removing particles in the injector 40 according to the present embodiment may be appropriately determined depending on a status of occurrence of particles.

In a case where a plurality of injectors 40 is provided, the bypass pipe 52 and the valves 61 and 62 may be installed in a corresponding relationship with the respective injectors 40. Furthermore, the bypass pipe 52 and the valves 61 and 62 may be installed only in the injector 40 for supplying a raw material gas, which is most likely to generate particles. In such an embodiment, an appropriate configuration may be adopted depending on the intended use.

According to the present disclosure in some embodiments, it is possible to effectively remove particles in an injector for supplying a processing gas to a substrate processing apparatus.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus, comprising:
a process vessel configured to accommodate and process a substrate;
a first injector located inside the process vessel and configured to discharge a first processing gas into the process vessel;
a processing gas supply pipe located outside of the process vessel and connected to the first injector and configured to supply the first processing gas to the first injector;
a first valve located in the processing gas supply pipe;
an exhaust part configured to exhaust the process vessel;
a bypass pipe branched at a predetermined position closer to the process vessel than the first valve in the processing gas supply pipe and configured to connect the processing gas supply pipe to the exhaust part; and
a second valve located in the bypass pipe.

2. The apparatus of claim 1, further comprising:
a controller configured to control operations of the first valve, the second valve and the exhaust part,
wherein the controller controls the exhaust part to exhaust an interior of the first injector while closing the first valve and opening the second valve prior to processing the substrate, and controls the first injector to supply the first processing gas into the process vessel while opening the first valve and closing the second valve when processing the substrate.

3. The apparatus of claim 2, wherein the process vessel and the exhaust part are connected with each other via an exhaust pipe, and
the bypass pipe is connected to the exhaust pipe.

4. The apparatus of claim 3, further comprising: a third valve located in the exhaust pipe,
wherein the controller closes the third valve when the exhaust part exhausts the interior of the first injector,

5. The apparatus of claim 3, wherein the second valve located in the bypass pipe is located in the vicinity of the predetermined position, and
the apparatus further comprises: a fourth valve located in the vicinity of the exhaust pipe connected to the bypass pipe.

6. The apparatus of claim 1, further comprising: a fifth valve located between the predetermined position of the processing gas supply pipe and the process vessel.

7. The apparatus of claim 1, further comprising:
a second injector configured to supply a second processing gas into the process vessel,
wherein the first injector is configured to supply, as the first processing gas, a raw material gas used when a film forming process is performed on the substrate, and
the second injector is configured to supply, as the second processing gas, a gas which reacts with the raw material gas to generate a reaction product.

8. The apparatus of claim 7, wherein the process vessel has a vertically-elongated substantially-cylindrical shape,
the first injector and the second injector vertically extending along an inner peripheral surface of the process vessel,
the substrate is mounted in a substrate holder configured to hold a plurality of substrates in a horizontal posture at vertical intervals, and
the apparatus further comprises: a heater located outside the process vessel and configured to heat the substrate.

9. The apparatus of claim 8, wherein the first injector and the second injector are configured to alternately supply the first processing gas and the second processing gas into the process vessel to perform an atomic layer deposition (ALD) film formation with respect to the substrate.

10. A method of removing particles in an injector, comprising:
connecting a processing gas supply pipe which is connected to a first injector installed inside a process vessel and configured to supply a first processing gas into the process vessel, to an exhaust part; and
exhausting, by the exhaust part, an interior of the first injector via the processing gas supply pipe.

11. The method of claim 10, further comprising: connecting the processing gas supply pipe to the exhaust part via a bypass pipe branched at a predetermined position in the processing gas supply pipe.

12. The method of claim 11, further comprising:
connecting the processing gas supply pipe to the exhaust part by closing a first valve located at an upstream side of the predetermined position of the processing gas supply pipe, and opening a second valve located in the bypass pipe.

13. The method of claim 12, further comprising:
installing an exhaust pipe with a third valve provided therein in the exhaust part;
connecting the exhaust part to the process vessel via the exhaust pipe, wherein the bypass pipe is connected to the exhaust pipe; and
closing a third valve located in the exhaust pipe when exhausting the interior of the first injector via the processing gas supply pipe, the exhaust pipe being connected the process vessel via the bypass pipe.

14. A substrate processing method, comprising:
performing the method of claim 13;
closing the second valve provided in the bypass pipe and opening the third valve provided in the exhaust pipe to exhaust an interior of the process vessel by the exhaust part; and
opening the first valve located in the processing gas supply pipe to supply the first processing gas from the first injector into the process vessel and to process a substrate inside the process vessel.

15. The method of claim 14, further comprising: installing a fourth valve in the vicinity of the exhaust pipe in the bypass pipe,
wherein the second valve located in the bypass pipe is located in the vicinity of the predetermined position, and
wherein the exhausting an interior of the process vessel by the exhaust part includes closing both the fourth valve and the second valve.

16. The method of claim 15, further comprising: installing a second injector configured to supply a second processing gas into the process vessel,
wherein the first injector is configured to supply, as the first processing gas, a raw material gas used when a film forming process is performed with respect to the substrate, and
wherein the second injector is configured to supply, as the second processing gas, a gas into the process vessel which reacts with the raw material gas to generate a reaction product.

17. The method of claim 16, further comprising: heating the substrate from a heater located outside the process vessel, wherein the process vessel has a vertically-elongated substantially-cylindrical shape,
the first injector and the second injector vertically extend along an inner peripheral surface of the process vessel, and
the substrate is mounted in a substrate holder configured to hold a plurality of substrates in a horizontal posture at vertical intervals.

18. The method of claim 17, wherein the first injector and the second injector are configured to alternately supply the first processing gas and the second processing gas into the process vessel to perform an ALD film formation with respect to the substrate.

19. The method of claim 15, further comprising: controlling operations of the first to fourth valves and the exhaust part with a controller.
